(19) United States
(12) Patent Application Publication
(10) Pub. No.: US 2025/0218957 A1
(43) Pub. Date: Jul. 3, 2025

(54) METHODS AND APPARATUS TO EMBED A SEMICONDUCTOR DEVICE IN A GLASS CORE

(71) Applicant: Intel Corporation, Santa Clara, CA (US)

(72) Inventors: Bohan Shan, Chandler, AZ (US); Srinivas Pietambaram, Chandler, AZ (US); Jose Fernando Waimin Almendares, Gilbert, AZ (US); Ryan Joseph Carrazzone, Chandler, AZ (US); Kyle Jordan Arrington, Gilbert, AZ (US); Ziyin Lin, Chandler, AZ (US); Haobo Chen, Chandler, AZ (US); Dingying Xu, Chandler, AZ (US); Hongxia Feng, Chandler, AZ (US); Gang Duan, Chandler, AZ (US); Xiaoying Guo, Chandler, AZ (US)

(21) Appl. No.: 18/398,633

(22) Filed: Dec. 28, 2023

(51) Int. Cl. H01L 23/538; H01L 23/00; H01L 23/15

(52) U.S. Cl. CPC H01L 23/5386; H01L 23/15; H01L 23/5384; H01L 24/32; H01L 24/16; H01L 2224/16227; H01L 2224/32225

(57) ABSTRACT

Systems, apparatus, articles of manufacture, and methods are disclosed to embed a semiconductor device in a glass core. An example apparatus comprises a package substrate comprising a glass core having a cavity in an outer surface of the glass core, the outer surface defining a first plane, and a semiconductor die attached to a surface of the cavity, the semiconductor die having contact pads on a surface of the semiconductor die, the contact pads arranged in a second plane, the second plane substantially coplanar with the first plane.

### FIELD OF THE DISCLOSURE

This disclosure relates generally to semiconductor packages and, more particularly, to methods and apparatus to embed a semiconductor device in a glass core.

### BACKGROUND

In many electronic devices, integrated circuit (IC) chips and/or semiconductor dies are connected to larger circuit boards such as motherboards and/or other types of printed circuit boards (PCBs) via a package substrate. Some known IC packages utilize voltage regulators for power delivery applications. In some instances, capacitors and/or other semiconductor devices used for such voltage regulators can be included in the package substrate for an IC package.

### BRIEF DESCRIPTION OF THE DRAWINGS

FIG. 1 is a cross-sectional side view of an example integrated circuit (IC) package constructed in accordance with teachings disclosed herein.

FIG. 2 is a cross-sectional side view of a portion of an example package substrate constructed in accordance with teachings disclosed herein.

FIGS. 3A-3D illustrate example glass cores constructed in accordance with teachings disclosed herein.

FIG. 4 is a flowchart representative of an example method to manufacture an example package substrate disclosed herein.

FIGS. 5A-5F illustrate different stages in an example process of manufacturing the example package substrates of FIGS. 5E and 5F.

FIGS. 6A-6E illustrate different stages in an example process of manufacturing the example package substrates of FIGS. 6D and 6E.

FIGS. 7A-7E illustrate different stages in an example process of manufacturing the example package substrates of FIGS. 7D and 7E.

FIGS. 8A-8D illustrate different stages in an example process of manufacturing the example package substrates of FIGS. 8C and 8D.

FIG. 9 is a top view of a wafer including dies that may be included in an IC package constructed in accordance with teachings disclosed herein.

FIG. 10 is a cross-sectional side view of an IC device that may be included in an IC package constructed in accordance with teachings disclosed herein.

FIG. 11 is a cross-sectional side view of an IC device assembly that may include an IC package constructed in accordance with teachings disclosed herein.

FIG. 12 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

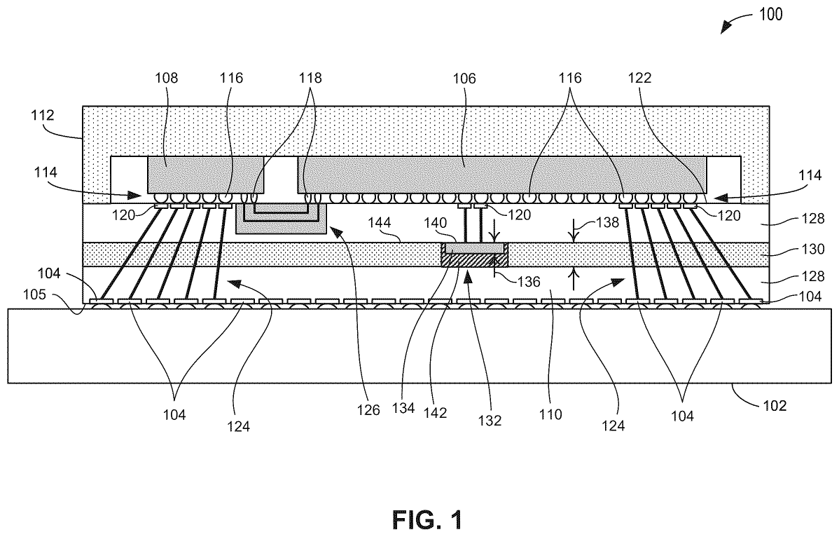

FIG. 1 illustrates an example integrated circuit (IC) package 100 constructed in accordance with teachings disclosed herein. In the illustrated example, the IC package 100 is electrically coupled to a circuit board 102 via an array of contact pads or lands 104 on a mounting surface 105 (e.g., a bottom surface) of the package. In some examples, the IC package 100 may include balls, pins, and/or pads, in addition to or instead of the contact pads 104, to enable the electrical coupling of the package 100 to the circuit board 102. In this example, the package 100 includes two semiconductor (e.g., silicon) dies 106, 108 (sometimes also referred to as chips or chiplets) that are mounted to a package substrate 110 and enclosed by a package lid or mold compound 112. Thus, the package substrate 110 is an example means for supporting a semiconductor die. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

As shown in the illustrated example, each of the dies 106, 108 is electrically and mechanically coupled to the substrate 110 via corresponding arrays of interconnects 114. In FIG. 1, the interconnects 114 are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. More particularly, as shown in the illustrated example, when the dies 106, 108 are mounted to the package substrate 110, the core bumps 116 are physically connected and electrically coupled to contact pads 120 on an inner surface 122 of the substrate 110. The contact pads 120 on the inner surface 122 of the package substrate 110 are electrically coupled to the pads 104 on the bottom (external) surface 105 of the substrate 110 (e.g., a surface opposite the inner surface 122) via internal interconnects 124 within the substrate 110. As a result, there is a continuous electrical signal path between the interconnects 114 of the dies 106, 108 and the pads 104 mounted to the circuit board 102 that pass through the contact pads 120 and the interconnects 124 provided therebetween.

As used herein, the bridge bumps 118 are bumps on the dies 106, 108 through which electrical signals pass between different ones of the dies 106, 108 within the package 100. Thus, as shown in the illustrated example, the bridge bumps 118 of the first die 106 are electrically coupled to the bridge bumps 118 of the second die 108 via an interconnect bridge 126 embedded in the package substrate 110. As represented in FIG. 1, core bumps 116 are typically larger than bridge bumps 118. In some examples, the interconnect bridge 126 and the associated bridge bumps 118 are omitted.

For purposes of illustration, the internal interconnects 124 are shown as straight lines extending directly between the pads 104 on the bottom surface 105 and the contact pads on the inner surface 122. However, in some examples, the internal interconnects 124 are defined by traces or routing in separate conductive (e.g., metal) layers within build-up regions 128 on one or both sides of a substrate core 130 in the package substrate 110. In such examples, the build-up regions 128 include dielectric layers to separate the different conductive layers. In such examples, the traces or routing in the different conductive layers are electrically coupled (to define the complete electrical path of the internal interconnects 124) by conductive (e.g., metal) vias extending between the different conductive layers. Further, in some examples, the internal interconnects 124 include vias that extend through the substrate core 130.

In some examples, the substrate core 130 is a glass substrate or core. In some examples, glass substrates (e.g., the glass core 130) includes quartz, fused silica, and/or borosilicate glass. In some examples, glass substrates (e.g., the glass core 130) includes at least 20% (by weight) of each of silicon (Si) and oxygen (O). In other examples, glass substrates (e.g., the glass core 130) includes greater amounts of at least one of silicon or oxygen (e.g., at least 25 wt %, at least 30 wt %, at least 35 wt %, at least 40 wt %, etc.). In some examples, glass substrates (e.g., the glass core 130) includes at least 5% (by weight) of aluminum (Al). In accordance with the present disclosure, glass substrates (e.g., the glass core 130) include at least one glass layer and do not include epoxy and does not include glass fibers (e.g., does not include an epoxy-based prepreg layer with glass cloth). In some examples, glass substrates (e.g., the glass core 130) correspond to a single piece of glass that extends the full height/thickness of the core. In some examples, the glass core 130 has a rectangular shape that is substantially coextensive, in plan view, with the layers above and below the core (e.g., substantially coextensive with the build-up regions 128). The substrate core 130, whether an organic core or a glass core, provides stiffness and mechanical support or strength for the package substrate 110 and the rest of the package 100. Thus, the substrate core 130 is an example means for strengthening the package substrate 110. In some examples, the thickness of the core 130 is driven by the size (e.g., footprint) of the package 100. For example, in some instances, larger packages 100 include a substrate 110 with a larger (e.g., thicker) core 130 as compared with smaller packages 100 where the core does not need to be as thick.

As shown in the illustrated example, the substrate core 130 includes an example cavity 132 in which an example semiconductor device 134 is embedded. In some examples, the semiconductor device 134 is a passive semiconductor die (e.g., a die that does not include transistors). In this example, the semiconductor device 134 is a deep trench capacitor die (also referred to herein as a deep trench capacitor for short). In some such examples, the deep trench capacitor is used to enable efficient power delivery to a fully integrated voltage regulator within the first die 106 in the IC package 100. In other examples, other types of semiconductor devices can be embedded within the cavity 132 of the substrate core 130 in addition to or instead of a deep trench capacitor. In some examples, more than one semiconductor device 134 can be embedded within the cavity 132 of the substrate core 130. In some examples, the substrate core 130 can include multiple cavities each containing one or more separate semiconductor devices 134.

As noted above, in this example, the semiconductor device 134 is a deep trench capacitor and may be referred to as such herein. As shown in the illustrated example, the deep trench capacitor 134 is electrically coupled to the first die 106. In some examples, the deep trench capacitor 134 is positioned in close proximity to the first die 106 (e.g., within the substrate core 130 rather than spaced farther away like land-side capacitors) to reduce inductance and parasitic effects, thereby increasing the effectiveness of the capacitor 134 (and/or achieving a given capacitance with a smaller sized capacitor). However, a challenge with embedding a deep trench capacitor 134 within a core 130 of a substrate arises from the thickness mismatch between the deep trench capacitor 134 and the core 130. In this example, the deep trench capacitor 134 is constructed through wafer-level processing from a semiconductor (e.g., silicon) wafer. Due to the nature of such wafer-level processing, the deep trench capacitor 134 has a thickness 136 limited to less than or equal to approximately 800 micrometers (μm) or less (e.g., less than or equal to approximately 700 μm, less than or equal to approximately 650 μm, less than or equal to approximately 600 μm, etc.). By contrast, the substrate core 130 can be significantly thicker, especially for larger packages as noted above. For instance, in some examples, the core 130 has a thickness 138 that is at least 20% greater than the thickness 136 of the deep trench capacitor 134 or more (e.g., at least 25% greater, at least 30% greater, at least 50% greater, at least 75% greater, at least twice as great, etc.). More specifically, in some examples, the thickness 138 of the core 130 is greater than approximately 800 μm or more (e.g., greater than or equal to approximately 1 millimeter (mm) (e.g., 1000 μm), greater than or equal to approximately 1.2 mm, greater than or equal to approximately 1.4 mm, greater than or equal to approximately 1.5 mm, etc.). Thus, as shown in FIG. 1, the thickness 136 of the deep trench capacitor 134 is less than the thickness 138 of the core 130.

The mismatch between the thicknesses 136, 138 of the deep trench capacitor 134 and the core 130 presents challenges in positioning the deep trench capacitor 134 within the cavity 132 of the core 130. Specifically, the relatively small size of the deep trench capacitor 134 can result in misalignments in any of the x, y, and z axes and/or rotational shifting or tilting because of the difficulty in securing the deep trench capacitor in place. In particular, the use of adhesives and/or an encapsulant (e.g., an example adhesive material 142 such as a dispensable liquid adhesive) to hold the deep trench capacitor 134 in place can be difficult because of the large space within the cavity 132 that needs to be filled which can result in a relatively long time for the adhesive and/or encapsulant to set or cure during which the deep trench capacitor 134 may shift, rotate, or otherwise move. As a result, a contact surface 140 of the deep trench capacitor 134 (e.g., a surface containing contacts with which the deep trench capacitor 134 is electrically coupled to (and facing towards) the first die 106) may not be aligned (e.g., flush) with a corresponding surface 144 (also facing towards the first die 106) of the glass core 130. Such misalignment can negatively affect the ability of the deep trench capacitor 134 to electrically connect with the interconnects within the build-up regions 128 above the core 130. Furthermore, the non-homogeneity of materials within the cavity 132 (e.g., the deep trench capacitor 134 and a relatively large volume of adhesive and/or encapsulant) can create processing challenges downstream and/or increase risks of warpage, mechanical stress, and/or thermomechanical stress in the package substrate 110.

Examples disclosed herein overcome the above challenges by providing a step, platform, recessed surface, or other structure to fill much of the space within the cavity 132 and support/embed the deep trench capacitor 134 at a suitable height and at a suitable location relative to the glass core 130. For example, disclosed examples provide (e.g., pattern) such a platform in the glass core 130 via laser etching and/or wet etching. Further, disclosed examples can include platforms of varying heights, depths, etc., within the glass core 130 based on a size and/or shape of the deep trench capacitor 134 to ensure the deep trench capacitor 134 is aligned with the surface 144 of the glass core 130. For example, platforms disclosed herein can vary in shape based on a size and/or shape of the deep trench capacitor 134. Examples disclosed herein provide example platforms to support (e.g., secure) the deep trench capacitor 134 during assembly, handling, etc., of the example IC package 100. In some examples disclosed herein, adhesive material is provided in the cavity 132 to surround or otherwise contact the deep trench capacitor 134. In such examples, the platforms can provide the deep trench capacitor 134 with additional stability when the adhesive material is added (e.g., deposited, inserted, etc.) in the cavity 132. In other examples, a die attach film (DAF) may be disposed (e.g., dispensed) on the deep trench capacitor 134 to facilitate attachment to a surface of (e.g., a platform in) the cavity 132. Additionally, examples disclosed herein can provide a through glass via (TGV) that extends through the glass core 130 from the deep trench capacitor 134. Examples disclosed herein enable the IC package 100 (and the glass core 130) to include the deep trench capacitor 134 to increase (e.g., free up) signal routing in adjacent layers (e.g., the build-up regions 128) and improve the overall capacitance of the IC package 100.

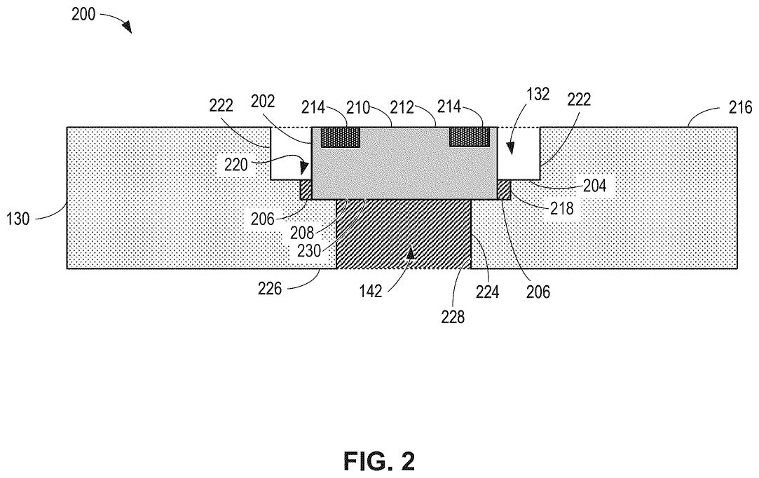

FIG. 2 illustrates a portion of an example package substrate 200 constructed in accordance with examples disclosed herein. The example package substrate 200 includes the glass core 130 having the example cavity 132 positioned in the glass core 130. The example package substrate 200 includes an example semiconductor device (e.g., the semiconductor device 134, semiconductor die, capacitor, etc.) 202 attached to a first example surface 204 of the cavity 132. In particular, the glass core 130 includes an example recessed surface 206 (e.g., mounting surface, platform, etc.) of the glass core 130 in the cavity 132 to support the semiconductor device 202. The example semiconductor device 202 includes a first example side 208 facing the recessed surface 206 and a second example side 210 opposite the first side 208. In this example, the second side 210 includes a second example surface 212 of the semiconductor device 202. Further, the second example surface 212 includes example contact pads 214.

As shown in FIG. 2, the second example side 210 of the semiconductor device 202 is substantially flush (e.g., within 2 degrees, offset by less than 15 μm) with a third example surface (e.g., the surface 144, outer surface, etc.) 216 of the glass core 130. In other words, the second surface 212 of the semiconductor device 202 is substantially coplanar or flush (e.g., within 10 degrees) with the third surface 216. The third example surface 216 defines a first plane (e.g., reference plane) and the second surface 212 of the semiconductor device 202 defines a second plane, the second plane substantially coplanar with the first plane. In FIG. 2, the example contact pads 214 are arranged in (e.g., substantially flush with) the second plane. In some examples, the contact pads 214 may be recessed relative to the second surface 212 and, thus, recessed relative to the second plane. In other examples, the contact pads 214 may protrude from the second surface 212 and, thus, protrude from the second plane.

The first example surface 204 of the cavity 132 is recessed (e.g., sunken, offset, etc.) relative to the third surface 216 of the glass core 130. Additionally, the example recessed surface 206 is recessed relative to the first surface 204. Put differently, the cavity 132 may be a first example cavity, and the recessed surface 206 can define another (e.g., second) cavity within the cavity 132. Further, in some examples, the recessed surface 206 is substantially parallel (e.g., within 5 degrees) to the first surface 204.

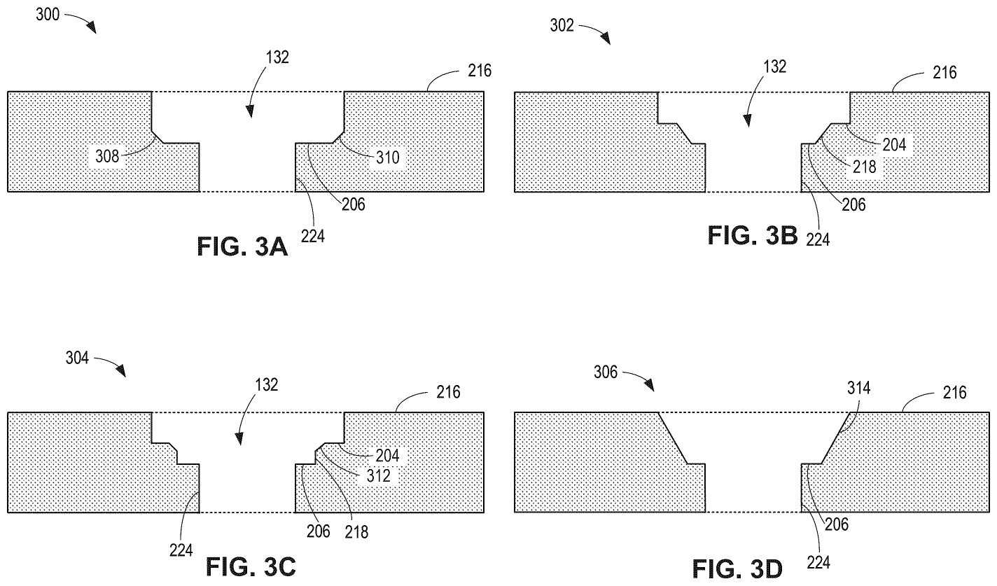

In FIG. 2, a fourth example surface 218 of the cavity 132 extends between the first surface 204 and the recessed surface 206. In some examples, the fourth example surface 218 is positioned substantially perpendicular (e.g., within 5 degrees) to the third surface 216 of the glass core 130. However, the fourth example surface 218 may be positioned at any angle relative to the third surface 216, described in detail in connection with FIG. 3B. In some examples, the first surface 204 and the fourth surface 218 may define an example ridge 220 positioned in the cavity 132. The example ridge 220 may extend along (e.g., adjacent to) an example edge of the semiconductor device 202. In some examples, the ridge 220 extends completely (e.g., continuously) around a full perimeter of the semiconductor device 202. In other examples, the ridge 220 extends along a discrete segment of the semiconductor device 202 (e.g., a single side of the device 202). In some such examples, the ridge 220 includes multiple discrete portions that extend along different segments of the semiconductor device 202 (e.g., along opposite sides of the device 202). In this example, the ridge 220 extends from example sidewall(s) 222 of the cavity 132 towards the semiconductor device 202. Further, the example ridge 220 extends from the recessed surface 206 towards the third surface 216 of the glass core 130.

The example glass core 130 includes an example via 224 that extends through the glass core 130. In particular, the example via 224 extends from the cavity 132 to a fifth example surface 226 of the glass core 130. The fifth example surface 226 opposes the third surface 216 of the glass core 130. As such, the semiconductor device 202 is positioned between the via 224 and the third surface 216. As shown in FIG. 2, an example opening (e.g., width, diameter, etc.) of the cavity 132 (in the third surface 216) is greater than an example opening (e.g., width, diameter, etc.) of the via 224 (in the fifth surface 226).

Further, the example package substrate 200 includes the adhesive material 142 in (e.g., to fill) the via 224. The example adhesive material 142 covers an example inner wall 228 of the via 224 from the semiconductor device 202 to the fifth surface 226. Further, the example adhesive material 142 extends at least partially into the cavity 132 to contact the semiconductor device 202. For example, the adhesive material 142 can contact a sixth example surface 230 of the semiconductor device 202 (corresponding to the first side 208 of the semiconductor device 202). In this example, the adhesive material 142 may facilitate bonding between the semiconductor device 202 and the glass core 130. In some examples, the adhesive material 142 is disposed between the sixth surface 230 and the recessed surface of the recessed surface 206. In some examples, the adhesive material 142 at least partially fills the portion of the cavity 132 surrounding the semiconductor device 202 above the sixth surface 230 (e.g., bottom side) of the semiconductor device 202. For instance, in the illustrated example, the adhesive material 142 extends up to (but not onto or beyond) the first surface 204. In other examples, the adhesive material 142 is spaced apart from and below (e.g., does not extend up to) the first surface 204. In other examples, the adhesive material 142 extends beyond and onto the first surface 204. In some examples, the adhesive material 142 extends all the way up to the third surface 216 at the top of the cavity 132. In examples where the adhesive material 142 fills less than all of the open space within the cavity 132 (e.g., the space surrounding the semiconductor device 202), the remaining space within the cavity 132 may be filled with a separate dielectric material during a dielectric film lamination process performed subsequent to the stage of manufacturing represented in FIG. 2.

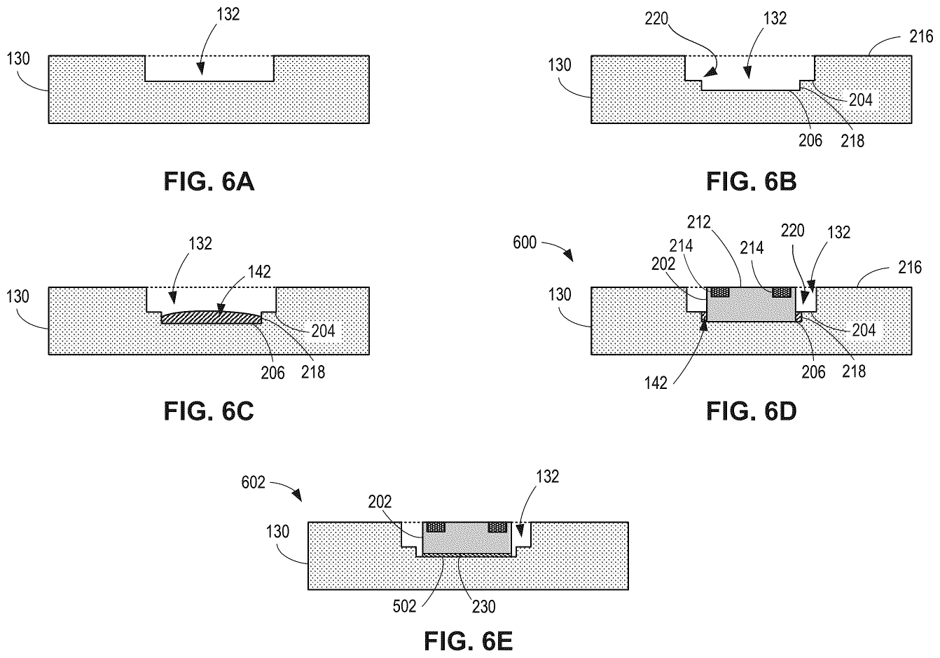

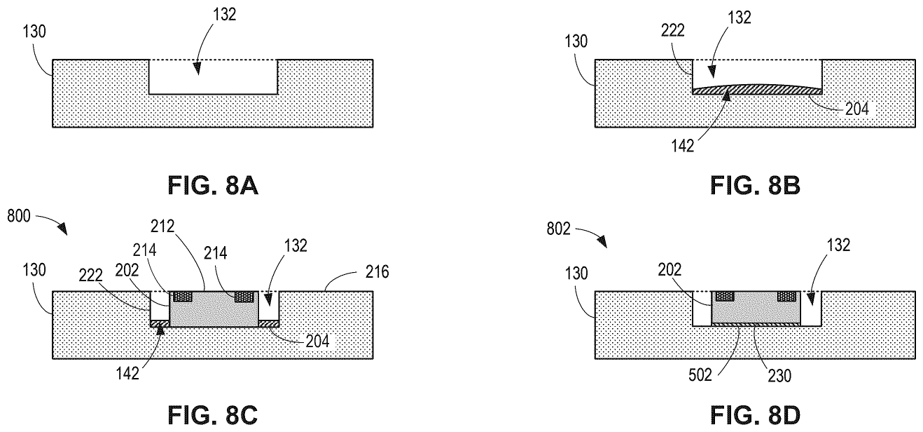

FIGS. 3A-3D illustrate example glass cores 300, 302, 304, 306 constructed in accordance with examples disclosed herein. In some examples, at least one of the glass cores 300, 302, 304, 306 may be implemented as the glass core 130 (FIGS. 1 and 2). In the examples of FIGS. 3A-3D, the example glass cores 300, 302, 304, 306 include the via 224. However, the example via 224 may be optionally excluded from any of the glass cores 300, 302, 304, 306, as described in detail in connection with at least FIGS. 6A-6E and 8A-8D.

Turning to FIG. 3A, the example glass core 300 is similar to the glass core 130 of FIG. 2 with the third surface 216 and the cavity 132. However, the example glass core 300 includes a seventh example surface 308 of the cavity 132 that is positioned at a first angle relative to the third surface 216 of the glass core 300. Additionally, an eighth example surface 310 of the cavity 132 is positioned at a second angle relative to the third surface 216. As shown in FIG. 3A, the first angle is different from the second angle (though, in some examples, the first and second angles may be symmetric). In some examples, at least one of the first angle or the second angle may be an acute angle (e.g., less than 90 degrees). Further, in some examples, the seventh example surface 308 is distinct from the eighth surface 310. The recessed surface 206 of the cavity 132 is likewise distinct from each of the seventh and eighth surfaces 308, 310. In FIG. 3A, the angled seventh and eighth surfaces 308, 310 form an example fillet (e.g., similar to the ridge 220 in FIG. 2).

Turning to FIG. 3B, the glass core 302 is similar to the glass core 130 of FIG. 2 with the recessed surface 206 recessed relative to the first surface 204. However, the fourth example surface 218 of the cavity 132 in the glass core 302 is positioned at an angle (e.g., relative to the third surface 216 of the glass core 302). Put differently, the fourth example surface 218 is a slanted (e.g., tilted, sloped, tapered, etc.) surface that is slanted relative to the first surface 204 and the recessed surface 206 of the cavity 132. In the example of FIG. 3B, the first surface 204 of the cavity 132 is substantially parallel with the third surface 216 of the glass core 130.

Turning to FIG. 3C, the example glass core 304 is similar to the glass core 130 of FIG. 2 with the recessed surface 206 recessed relative to the first surface 204. However, the glass core 304 includes a ninth example surface 312 positioned between the fourth surface 218 and the first surface 204 of the cavity 132. Further, the ninth example surface 312 is positioned at an angle (e.g., slant) relative to the fourth surface 218 and the first surface 204. In other words, the ninth surface 312 defines a chamfered edge or corner between the first surface 204 and the fourth surface 218.

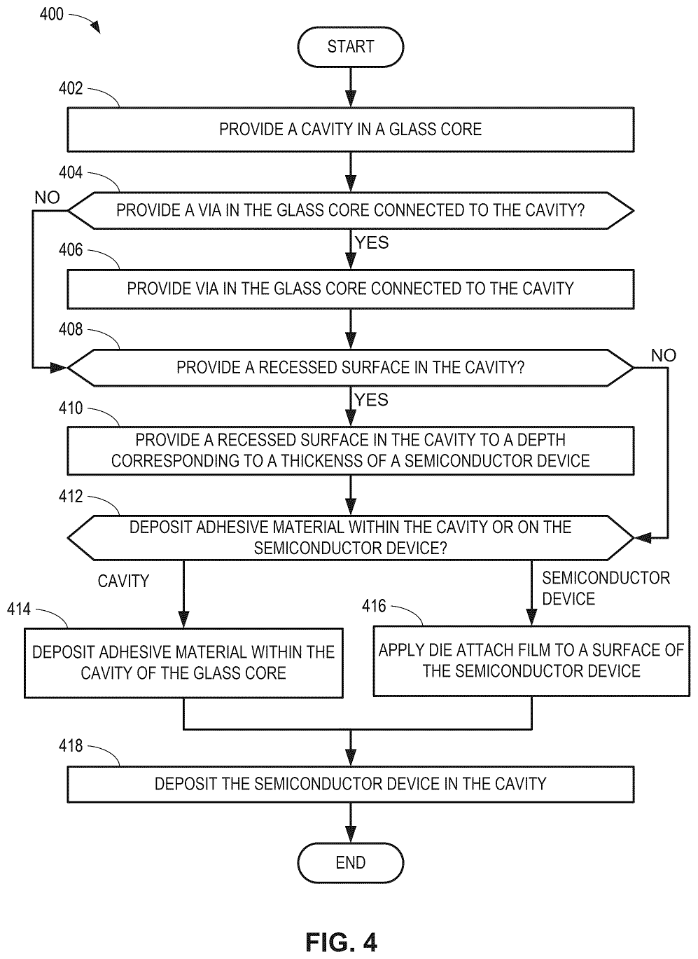

Turning to FIG. 3D, the example glass core 304 is similar to the glass core 130 of FIG. 2 with the recessed surface 206 recessed relative to the third surface 216. However, the example glass core 306 includes a tenth example surface 314 of the cavity 132 positioned between the recessed surface 206 and the third surface 216. Further, the tenth example surface 314 is positioned at a third angle relative to the third surface 216 of the glass core 306. When the semiconductor device 202 is positioned in any of the glass cores 300, 302, 304, 306 (a process described in connection with FIG. 4), the example surfaces 218, 310, 312, 314 may provide a guide and/or support to position (e.g., slide) the semiconductor device 202 (FIG. 2) into place on the recessed surface 206 (or the first surface 204 of the glass core 306).

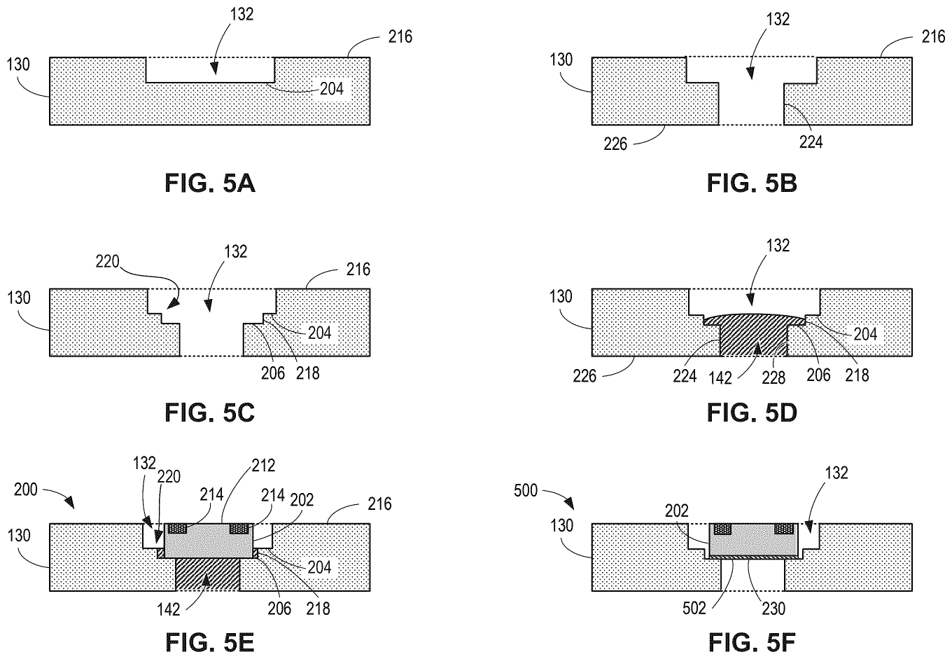

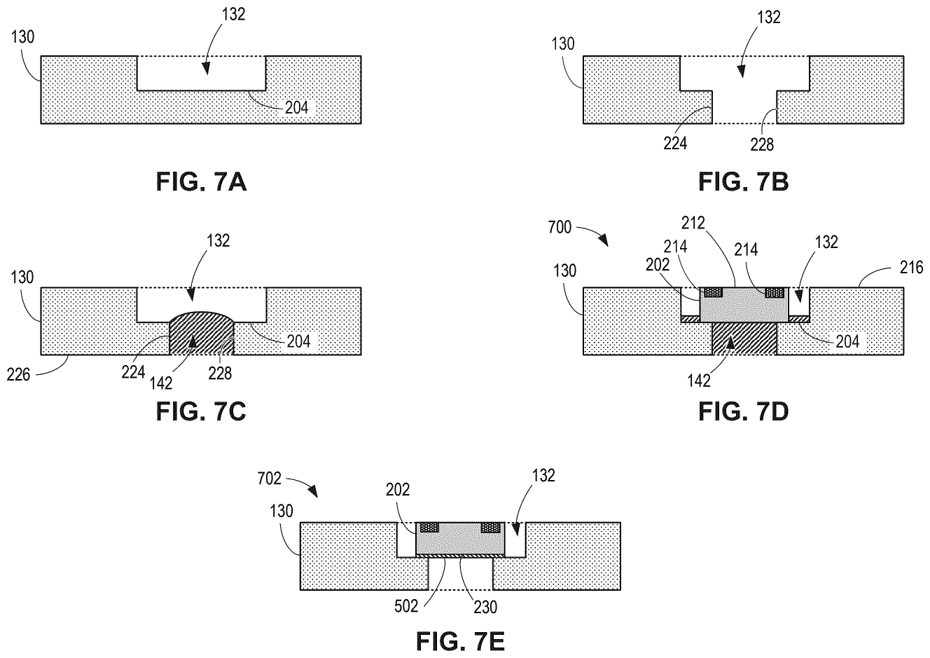

FIG. 4 is a flowchart representative of an example method 400 to produce the example package substrate 200 of FIGS. 2 and 5E, a portion of an example package substrate 500 of FIG. 5F, a portion of an example package substrate 600 of FIG. 6D, a portion of an example package substrate 602 of FIG. 6E, a portion of an example package substrate 700 of FIG. 7D, a portion of an example package substrate 702 of FIG. 7E, a portion of an example package substrate 800 of FIG. 8C, and a portion of an example package substrate 802 of FIG. 8D. FIGS. 5A-5E represent the example package substrate 200 at various stages during the example process described in FIG. 4. FIGS. 5A-5C and 5F represent the example package substrate 500 at various stages during the example process described in FIG. 4. FIGS. 6A-6D represent the example package substrate 600 at various stages during the example process described in FIG. 4. FIGS. 6A, 6B, and 6E represent the example package substrate 602 at various stages during the example process described in FIG. 4. FIGS. 7A-7D represent the example package substrate 700 at various stages during the example process described in FIG. 4. FIGS. 7A, 7B, and 7E represent the example package substrate 702 at various stages during the example process described in FIG. 4. FIGS. 8A-8C represent the example package substrate 800 at various stages during the example process described in FIG. 4. FIGS. 8A and 8D represent the example package substrate 802 at various stages during the example process described in FIG. 4. In some examples, some or all of the operations outlined in the example method of FIG. 4 are performed automatically by fabrication equipment that is programmed to perform the operations. Although the example method of manufacture is described with reference to the flowchart illustrate in FIG. 4, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example. Although the example method of manufacture is described with reference to the glass core 130, any of the example glass cores 300, 302, 304, 306 may be implemented in the examples described in connection with FIGS. 5A-5F and 6A-6E.

Turning to FIG. 4, the example process begins at block 402 at which an example cavity is provided in an example glass core. As shown in FIG. 5A, the example cavity 132 is provided in the third surface 216 of the glass core 130. In this example, the third surface 216 defines a first plane. Further, the first example surface 204 of the cavity 132 is recessed relative to the third surface 216 of the glass core 130.

At block 404, it is determined whether an example via is to be provided in the example glass core connected to the cavity. If no via is to be provided, the process proceeds to block 408, as discussed below in connection with FIGS. 6A-6E and 8A-8D. If an example via is to be provided, the process proceeds to block 406. In the example process illustrated by FIGS. 5A-5F, an example via is provided. In such examples, the process proceeds to block 406.

At block 406, an example via is provided in the glass core connected to the cavity. As shown in FIG. 5B, the example via 224 is provided in the glass core 130 connected to the cavity 132. The example via 224 extends from the cavity 132 to the fifth surface 226 of the glass core 130. The fifth example surface 226 opposes the third example surface 216. Further, the example opening of the cavity 132 (in the third surface 216) is greater than the opening of the via 224 (in the fifth surface 226). The example opening of the cavity 132 is larger than the semiconductor device 202 so that the semiconductor device 202 can be received therein. Further, the example opening of the via 224 is smaller than the semiconductor device 202 so that the semiconductor device 202 can be supported by a portion of the glass core 130 surrounding the via 224.

At block 408, it is determined whether an example recessed surface is to be provided in the cavity. If no recessed surface is to be provided, the process proceeds to block 412, as discussed below in connection with FIGS. 7A-7E and 8A-8D. If an example recessed surface is to be provided, the process proceeds to block 410. In the example process illustrated by FIGS. 5A-5F, an example recessed surface is provided. In such examples, the process proceeds to block 410. Although the example process illustrated by FIGS. 5A-5F describe that a recessed surface may be provided in the cavity after a via is provided in the cavity, the example process illustrated by FIGS. 5A-5F may also provide a via in the cavity after a recessed surface is provided in the cavity.

At block 410, an example recessed surface is provided in the cavity to a depth corresponding to a thickness of an example semiconductor device. As shown in FIG. 5C, the example recessed surface 206 is provided in the first surface 204 of the cavity 132. In this example, the distance between the recessed surface 206 and the third surface 216 substantially matches (e.g., within 25 μm) a thickness of the semiconductor device 202 (e.g., a thickness less than 800 μm) (FIG. 2). In some examples, the depth of the recessed surface 206 relative to the top surface (e.g., the third surface 216) of the glass core 130 is slightly more than the thickness of the semiconductor device 202 to account for the thickness of an adhesive material between the semiconductor device 202 and the recessed surface 206 on which the device 202 is to be mounted and attached as discussed further below. The fourth example surface 218 of the cavity 132 extends between the first surface 204 and the recessed surface 206. The fourth example surface 218 is positioned substantially perpendicular (e.g., within 5 degrees) to the third surface 216 of the glass core 130. The first example surface 204 and the fourth surface 218 may define the ridge 220. In some examples, the cavity 132 and/or the recessed surface 206 may be shaped to achieve any of the examples shown in FIGS. 3A-3D.

At block 412, it is determined whether example adhesive material is to be deposited (e.g., provided, applied, etc.) within the cavity or on the semiconductor device. In some examples, adhesive material may be deposited within the cavity and on the semiconductor device. If example adhesive material is to be provided on the semiconductor device, the process proceeds to block 416, as discussed below in connection with FIGS. 5F, 6E, 7E, and 8D. If example adhesive material is to be provided within the cavity, the process proceeds to block 414. In the example process illustrated by FIGS. 5A-5E, adhesive material is to be provided within the cavity. In such examples, the process proceeds to block 414.

At block 414, example adhesive material is deposited within the cavity. As shown in FIG. 5D, the example adhesive material 142 is deposited within the cavity 132. The example adhesive material 142 covers the inner wall 228 of the via 224 from at least the recessed surface 206 to the fifth surface 226. Thus, in some examples, the example adhesive material 142 extends at least partially into the cavity 132 to contact the fourth surface 218.

At block 418, an example semiconductor device is deposited in the cavity. As shown in FIG. 5E, the example semiconductor device 202 is deposited in the cavity 132. The example ridge 220 may guide and/or position the semiconductor device 202 to the recessed surface 206 when the semiconductor device 202 is being deposited into the cavity 132. Alternatively, an angled surface (e.g., the surfaces 218, 310, 312, 314) of an example glass core (e.g., the glass cores 300, 302, 304, 306) may provide such a guide and/or support to position (e.g., slide) the semiconductor device 202 into place on the recessed surface 206 (or the first surface 204 of the glass core 306). The example semiconductor device 202 includes a thickness that substantially matches the distance between the recessed surface 206 and the third surface 216. The example adhesive material 142 may provide some thickness between the semiconductor device 202 and the recessed surface 206. However, the depth of the example recessed surface 206 relative to the third surface 216 may be slightly more than the thickness of the semiconductor device 202 to account for any thickness provided by the adhesive material 142. As such, the second example surface 212 of the semiconductor device 202 is substantially flush with the third surface 216 of the glass core 130. The second example surface 212, including the contact pads 214, defines a second plane that is substantially coplanar with the first plane (e.g., the first plane defined by the third surface 216). Further, the adhesive material 142 may facilitate bonding between the semiconductor device 202 and the glass core 130.

Returning to block 412, if it is determined that example adhesive material is to be deposited on the semiconductor device, then the process proceeds to block 416 with the subsequent stage(s) of fabrication represented by FIG. 5F. At block 416, example die attach film (DAF) is applied to the surface of the semiconductor device. As shown in FIG. 5F, an example DAF 502 is applied to the sixth surface 230 of the semiconductor device 202.

At block 418, the example semiconductor device is deposited in the cavity. As shown in FIG. 5F, the example semiconductor device 202 is deposited in the cavity 132. In this example, the DAF 502 facilitates a bond between the semiconductor device 202 and the glass core 130. The example DAF 502 may provide some thickness between the semiconductor device 202 and the recessed surface 206. However, the depth of the example recessed surface 206 relative to the third surface 216 may be slightly more than the thickness of the semiconductor device 202 to account for any thickness provided by the DAF 502.

Returning to block 404, if it is determined that an example via is not to be provided in the glass core, then the process proceeds to block 408 with the subsequent stages of fabrication represented by FIGS. 6A-6E. At block 408, it is determined whether to provide an example recessed surface in the cavity. In the example process illustrated by FIGS. 6A-6E, an example recessed surface is to be provided on the glass core. In such examples, the process proceeds to block 410.

At block 410, an example recessed surface is provided in the cavity to a depth corresponding to a thickness of an example semiconductor device. As shown in FIG. 6B, the example recessed surface 206 is provided in the cavity 132 in the glass core 130 (FIG. 6A). In this example, the distance between the recessed surface 206 and the third surface 216 substantially matches a thickness of the semiconductor device 202 (FIG. 2). In some examples, the depth of the recessed surface 206 relative to the third surface 216 is slightly more than the thickness of the semiconductor device 202 to account for the thickness of an adhesive material between the semiconductor device 202 and the recessed surface 206 on which the device 202 is to be mounted an attached as discussed further below. In this example, the cavity 132 may be a first example cavity such that the recessed surface 206 can define a second example cavity, the second cavity positioned in the first surface 204 of the first cavity 132. In some examples, the first surface 204 and the fourth surface 218 may define the ridge 220. In some examples, the cavity and/or the recessed surface 206 may be shaped to achieve any of the example shown in FIGS. 3A-3D (e.g., without the via 224).

At block 412, it is determined whether example adhesive material is to be provided within the cavity or on the semiconductor device. If example adhesive material is to be provided on the semiconductor device, the process proceeds to block 416, as discussed below in connection with FIGS. 6E, 7E, and 8D. If example adhesive material is to be provided within the cavity, the process proceeds to block 414. In the example process illustrated by FIGS. 6A-6D, adhesive material is to be provided within the cavity. In such examples, the process proceeds to block 414.

At block 414, example adhesive material is deposited within the cavity. As shown in FIG. 6C, the example adhesive material 142 is deposited within the cavity 132. In particular, the example adhesive material 142 is positioned in the cavity 132. As such, the example adhesive material 142 contacts the recessed surface 206 of the cavity 132 and the fourth surface 218.

At block 418, the example semiconductor device is deposited in the cavity. As shown in FIG. 6D, the example semiconductor device 202 is deposited in the cavity 132. In particular, the example semiconductor device 202 is mounted to the recessed surface 206 (e.g., in the second cavity). In such examples, the recessed surface 206 may be referred to as an example support surface (e.g., landing surface, landing plane, etc.). The example ridge 220 may guide and/or position the semiconductor device 202 to the recessed surface 206 when the semiconductor device 202 is being deposited into the cavity 132. Alternatively, an angled surface (e.g., the surfaces 218, 310, 312, 314) of an example glass core (e.g., the glass cores 300, 302, 304, 306) may provide such a guide and/or support to position (e.g., slide) the semiconductor device 202 into place on the recessed surface 206 (or the first surface 204 of the glass core 306). The example semiconductor device 202 includes a thickness that substantially matches the distance between the recessed surface 206 and the third surface 216. The example adhesive material 142 may provide some thickness between the semiconductor device 202 and the recessed surface 206. However, the depth of the example recessed surface 206 relative to the third surface 216 may be slightly more than the thickness of the semiconductor device 202 to account for any thickness provided by the adhesive material 142. As such, the second example surface 212 of the semiconductor device 202 is substantially flush with the third surface 216 of the glass core 130. The second example surface 212, including the contact pads 214, defines a second plane that is substantially coplanar with the first plane (e.g., the first plane defined by the third surface 216). Further, the adhesive material 142 may facilitate bonding between the semiconductor device 202 and the glass core 130.

Returning to block 412, if it is determined that example adhesive material is to be deposited on the semiconductor device, then the process proceeds to block 416 with the subsequent stage(s) of fabrication represented by FIG. 6E. At block 416, example DAF is applied to the surface of the semiconductor device. As shown in FIG. 6E, the example DAF 502 is applied to the sixth surface 230 of the semiconductor device 202.

At block 418, the example semiconductor device is deposited in the cavity. As shown in FIG. 6E, the example semiconductor device 202 is deposited in the cavity 132. In this example, the DAF 502 facilitates a bond between the semiconductor device 202 and the glass core 130. The example DAF 502 may provide some thickness between the semiconductor device 202 and the recessed surface 206. However, the depth of the example recessed surface 206 relative to the third surface 216 may be slightly more than the thickness of the semiconductor device 202 to account for any thickness provided by the DAF 502.

Returning to block 408, if it is determined that no recessed surface is to be provided in the cavity, then the process proceeds to block 412 with the subsequent stage(s) of fabrication represented by FIGS. 7A-7E. At block 412, it is determined whether example adhesive material is to be provided within the cavity or on the semiconductor device. If example adhesive material is to be provided on the semiconductor device, the process proceeds to block 416, as discussed below in connection with FIGS. 7E and 8D. If example adhesive material is to be provided within the cavity, the process proceeds to block 414. In the example process illustrated by FIGS. 7A-7D, adhesive material is to be provided within the cavity. In such examples, the process proceeds to block 414.

At block 414, example adhesive material is deposited within the cavity. As shown in FIG. 7C, the example adhesive material 142 is deposited within the cavity 132 of the glass core 130 (e.g., FIG. 7A). The example adhesive material 142 covers the inner wall 228 of the via 224 (FIG. 7B) from the first surface 204 of the cavity 132 (FIG. 7A) to the fifth surface 226. Thus, the example adhesive material 142 extends at least partially into the cavity 132.

At block 418, the example semiconductor device is added to the cavity. As shown in FIG. 7D, the example semiconductor device 202 is added to the cavity 132. The example semiconductor device 202 includes a thickness that substantially matches the distance between the first surface 204 and the third surface 216. In this example, the glass core 130 is provided with cavity 132 that has a depth that corresponds to the thickness of the semiconductor device 202. Further, the first example surface 204 provides a mounting (e.g., support) surface on which the semiconductor device 202 is to attach. The example adhesive material 142 may provide some thickness between the semiconductor device 202 and the first surface 204. However, the depth of the example first surface 204 relative to the third surface 216 may be slightly more than the thickness of the semiconductor device 202 to account for any thickness provided by the adhesive material 142. As such, the second example surface 212 of the semiconductor device 202 is substantially flush with the third surface 216 of the glass core 130. The second example surface 212, including the contact pads 214, defines a second plane that is substantially coplanar with the first plane (e.g., the first plane defined by the third surface 216). Further, the adhesive material 142 may facilitate bonding between the semiconductor device 202 and the glass core 130.

Returning to block 412, if it is determined that example adhesive material is to be deposited on the semiconductor die, then the process proceeds to block 416 with the subsequent stage(s) of fabrication represented by FIG. 7E. At block 416, example DAF is applied to the surface of the semiconductor device. As shown in FIG. 7E, the example DAF 502 is applied to the sixth surface 230 of the semiconductor device 202.

At block 418, the example semiconductor device is deposited in the cavity. As shown in FIG. 7E, the example semiconductor device 202 is deposited in the cavity 132. In this example, the DAF 502 facilitates a bond between the semiconductor device 202 and the glass core 130. The example DAF 502 may provide some thickness between the semiconductor device 202 and the first surface 204. However, the depth of the example first surface 204 relative to the third surface 216 may be slightly more than the thickness of the semiconductor device 202 to account for any thickness provided by the DAF 502.

Returning to block 404, if it is determined that an example via is not to be provided in the glass core, then the process proceeds to block 408 with the subsequent stages of fabrication represented by FIGS. 8A-8D. At block 408, it is determined whether to provide an example recessed surface in the cavity. In the example process illustrated by FIGS. 8A-8D, an example recessed surface is not to be provided on the glass core. In such examples, the process proceeds to block 412.

At block 412, it is determined whether example adhesive material is to be provided within the cavity or on the semiconductor device. If example adhesive material is to be provided on the semiconductor device, the process proceeds to block 416, as discussed below in connection with FIG. 8D. If example adhesive material is to be provided within the cavity, the process proceeds to block 414. In the example process illustrated by FIGS. 8A-8C, adhesive material is to be provided within the cavity. In such examples, the process proceeds to block 414.

At block 414, example adhesive material is deposited within the cavity. As shown in FIG. 8B, the example adhesive material 142 is deposited within the cavity 132 of the glass core 130 (FIG. 8A). In particular, the example adhesive material 142 is positioned in the cavity 132 (FIG. 8A). As such, the example adhesive material 142 contacts the first surface 204 of the cavity 132 and portions of the sidewall(s) 222 of the cavity 132.

At block 418, the example semiconductor device is added to the cavity. As shown in FIG. 8C, the example semiconductor device 202 is added to the cavity 132. The example semiconductor device 202 includes a thickness that substantially matches the distance between the first surface 204 and the third surface 216. In this example, the glass core 130 is provided with cavity 132 that has a depth that corresponds to the thickness of the semiconductor device 202. Further, the first example surface 204 provides a mounting (e.g., support) surface on which the semiconductor device 202 is to attach. The example adhesive material 142 may provide some thickness between the semiconductor device 202 and the first surface 204. However, the depth of the first example surface 204 relative to the third surface 216 may be slightly more than the thickness of the semiconductor device 202 to account for any thickness provided by the adhesive material 142. As such, the second example surface 212 of the semiconductor device 202 is substantially flush with the third surface 216 of the glass core 130. The second example surface 212, including the contact pads 214, defines a second plane that is substantially coplanar with the first plane (e.g., the first plane defined by the third surface 216). In the example of FIG. 8C, the example adhesive material 142 contacts the semiconductor device 202 and portions of the sidewall(s) 222 of the cavity 132. As such, the adhesive material 142 may facilitate bonding between the semiconductor device 202 and the glass core 130.

Returning to block 412, if it is determined that example adhesive material is to be deposited on the semiconductor device, then the process proceeds to block 416 with the subsequent stage(s) of fabrication represented by FIG. 8D. At block 416, example DAF is applied to the surface of the semiconductor device. As shown in FIG. 8D, the example DAF 502 is applied to the sixth surface 230 of the semiconductor device 202.

At block 418, the example semiconductor device is deposited in the cavity. As shown in FIG. 8D, the example semiconductor device 202 is deposited in the cavity 132. In this example, the DAF 502 facilitates a bond between the semiconductor device 202 and the glass core 130. The example DAF 502 may provide some thickness between the semiconductor device 202 and the first surface 204. However, the depth of the first example surface 204 relative to the third surface 216 may be slightly more than the thickness of the semiconductor device 202 to account for any thickness provided by the DAF 502.

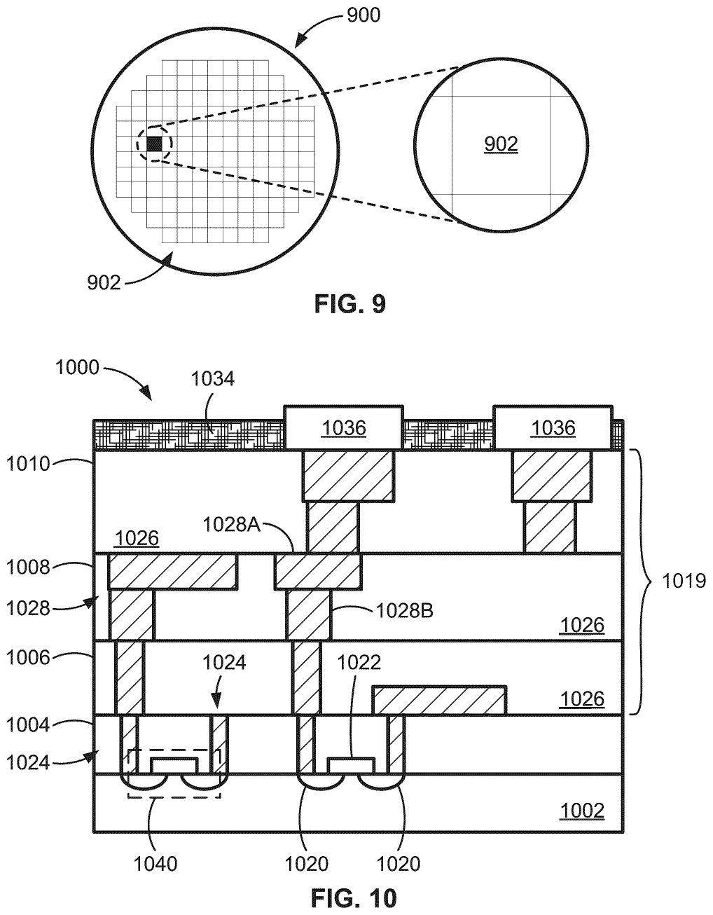

The example package substrates 200, 500, 600, 602, 700, 702, 800, 802 (e.g., any of the package substrates 200, 500, 600, 602, 700, 702, 800, 802 that include any of the glass cores 300, 302, 304, 306) disclosed herein may be included in any suitable electronic component, such as the example IC package 100. FIGS. 9-12 illustrate various examples of apparatus that may include the package substrates 200, 500, 600, 602, 700, 702, 800, 802 disclosed herein.

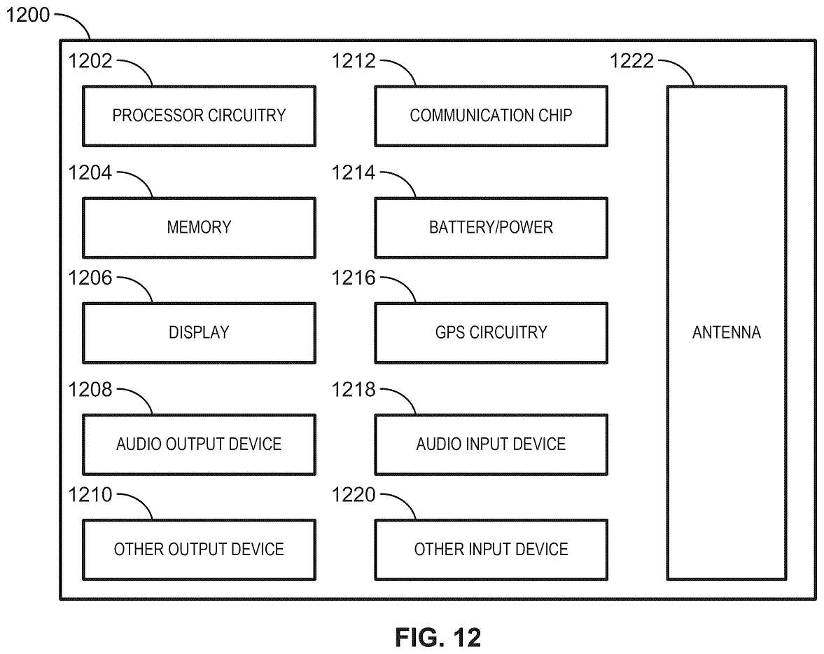

FIG. 9 is a top view of an example wafer 900 and dies 902 that may be included in the package substrates 200, 500, 600, 602, 700, 702, 800, 802 (e.g., as any suitable ones of the deep trench capacitor 134 or the semiconductor device 202) and/or mounted to any of the package substrates 200, 500, 600, 602, 700, 702, 800, 802 (e.g., as any suitable ones of the semiconductor dies 106, 108 of FIG. 1). The wafer 900 may be composed of semiconductor material and may include one or more dies 902 having circuitry. Some or all of the dies 902 may be a repeating unit of a semiconductor product. After the fabrication of the semiconductor product is complete, the wafer 900 may undergo a singulation process in which the dies 902 are separated from one another to provide discrete “chips.” The die 902 may include one or more transistors (e.g., some of the transistors 1040 of FIG. 10, discussed below), supporting circuitry to route electrical signals to the transistors, passive components (e.g., traces, resistors, capacitors, inductors, and/or other circuitry), and/or any other components. In some examples, the die 902 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 902. For example, a memory array formed by multiple memory circuits may be formed on a same die 902 as programmable circuitry (e.g., the processor circuitry 1202 of FIG. 12) or other logic circuitry. Such memory may store information for use by the programmable circuitry. The example IC package 100 disclosed herein may be manufactured using a die-to-wafer assembly technique in which some dies 106, 108, the deep trench capacitor 134, or the semiconductor device 202 are attached to a wafer 900 that include others of the dies 106, 108, the deep trench capacitor 134, or the semiconductor device 202 and the wafer 900 is subsequently singulated.

FIG. 10 is a cross-sectional side view of an example IC device 1000 that may be included in the example IC package 100 (e.g., in any one of the dies 106, 108, the deep trench capacitor 134, or the semiconductor device 202). One or more of the IC devices 1000 may be included in one or more dies 902 (FIG. 9). The IC device 1000 may be formed on an example die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some examples, the die substrate 1002 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an IC device 1000 may be used. The die substrate 1002 may be part of a singulated die (e.g., the dies 902 of FIG. 9) or a wafer (e.g., the wafer 900 of FIG. 9).

The IC device 1000 may include one or more example device layers 1004 disposed on or above the die substrate 1002. The device layer 1004 may include features of one or more example transistors 1040 (e.g., metal oxide semiconductor field-effect transistors (MOSFETs)) formed on the die substrate 1002. The device layer 1004 may include, for example, one or more example source and/or drain (S/D) regions 1020, an example gate 1022 to control current flow between the S/D regions 1020, and one or more example S/D contacts 1024 to route electrical signals to/from the S/D regions 1020. The transistors 1040 may include additional features not depicted for the sake of clarity such as, for example, device isolation regions, gate contacts, and the like. The transistors 1040 are not limited to the type and configuration depicted in FIG. 10 and may include a wide variety of other types and/or configurations such as, for example, planar transistors, non-planar transistors, or a combination of both. Non-planar transistors may include FinFET transistors such as for example, double-gate transistors, tri-gate transistors, wrap-around gate transistor, and/or all-around gate transistors, such as nanoribbon and/or nanowire transistors.

Some or all of the transistors 1040 may include an example gate 1022 formed of at least two layers including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included for other purposes, such as for example a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 1040 along the source-channel-drain direction, the gate electrode may include a U-shaped structure that includes a bottom portion substantially parallel to the surface of the die substrate 1002 and two sidewall portions that are substantially perpendicular to the top surface of the die substrate 1002. In other examples, at least one of the metal layers that form the gate electrode may be a planar layer that is substantially parallel to the top surface of the die substrate 1002 and does not include sidewall portions substantially perpendicular to the top surface of the die substrate 1002. In other examples, the gate electrode may include a combination of U-shaped structures and planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers include deposition and etching process steps. In some examples, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of respective ones of the transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes the dopants to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1020 may be formed using one or more alternate semiconductor materials such as germanium or a group III-V material or alloy. In further examples, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more example interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with example interconnect structures 1028 of the interconnect layers 1006-1010. The one or more interconnect layers 1006-1010 may form an example metallization stack (also referred to as an “ILD stack”) 1019 of the IC device 1000.

The interconnect structures 1028 may be arranged within the interconnect layers 1006-1010 to route electrical signals according to a wide variety of designs (in particular, the arrangement is not limited to the particular configuration of interconnect structures 1028 depicted in FIG. 10). Although a particular number of interconnect layers 1006-1010 is depicted in FIG. 10, examples of the present disclosure include IC devices having more or fewer interconnect layers than depicted.

In some examples, the interconnect structures 1028 may include example lines 1028a and/or example vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page from the perspective of FIG. 10. The vias 1028b may be arranged to route electrical signals in a direction of a plane that is substantially perpendicular to the surface of the die substrate 1002 upon which the device layer 1004 is formed. In some examples, the vias 1028b may electrically couple lines 1028a of different interconnect layers 1006-1010 together.

The interconnect layers 1006-1010 may include an example dielectric material 1026 disposed between the interconnect structures 1028, as shown in FIG. 10. In some examples, the dielectric material 1026 disposed between the interconnect structures 1028 in different ones of the interconnect layers 1006-1010 may have different compositions. In other examples, the composition of the dielectric material 1026 between different interconnect layers 1006-1010 may be the same.

A first interconnect layer 1006 (referred to as Metal 1 or “M1”) may be formed directly on the device layer 1004. In some examples, the first interconnect layer 1006 may include lines 1028a and/or vias 1028b, as shown. The lines 1028a of the first interconnect layer 1006 may be coupled with contacts (e.g., the S/D contacts 1024) of the device layer 1004.

A second interconnect layer 1008 (referred to as Metal 2 or “M2”) may be formed directly on the first interconnect layer 1006. In some examples, the second interconnect layer 1008 may include vias 1028b to couple the lines 1028a of the second interconnect layer 1008 with the lines 1028a of the first interconnect layer 1006. Although the lines 1028a and the vias 1028b are structurally delineated with a line within each interconnect layer (e.g., within the second interconnect layer 1008) for the sake of clarity, the lines 1028a and the vias 1028b may be structurally and/or materially contiguous (e.g., simultaneously filled during a dual-damascene process) in some examples.

A third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 and/or the first interconnect layer 1006. In some examples, the interconnect layers that are “higher up” in the metallization stack 1019 in the IC device 1000 (i.e., further away from the device layer 1004) may be thicker.

The IC device 1000 may include an example solder resist material 1034 (e.g., polyimide or similar material) and one or more example conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to other external devices. For example, solder bonds may be formed on the one or more conductive contacts 1036 to mechanically and/or electrically couple a chip including the IC device 1000 with another component (e.g., a circuit board). The IC device 1000 may include additional or alternate structures to route the electrical signals from the interconnect layers 1006-1010; for example, the conductive contacts 1036 may include other analogous features (e.g., posts) that route the electrical signals to external components.

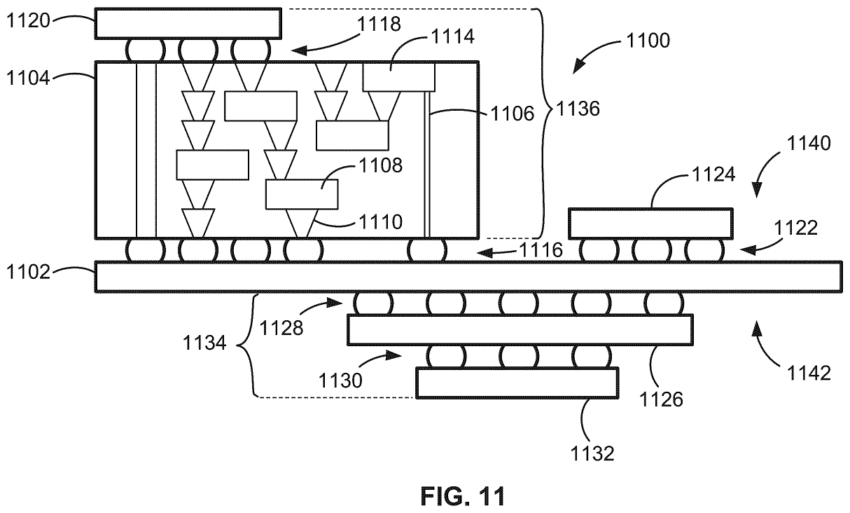

FIG. 11 is a cross-sectional side view of an example IC device assembly 1100 that may include the IC package 100 disclosed herein. In some examples, the IC device assembly corresponds to the IC package 100. The IC device assembly 1100 includes a number of components disposed on an example circuit board 1102 (which may be, for example, a motherboard). The IC device assembly 1100 includes components disposed on an example first face 1140 of the circuit board 1102 and an example opposing second face 1142 of the circuit board 1102. Any of the IC packages discussed herein with reference to the IC device assembly 1100 may take the form of the example IC package 100.

In some examples, the circuit board 1102 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1102. In other examples, the circuit board 1102 may be a non-PCB substrate. In some examples, the circuit board 1102 may be, for example, the circuit board 102 of FIG. 1.

The IC device assembly 1100 illustrated in FIG. 11 includes an example package-on-interposer structure 1136 coupled to the first face 1140 of the circuit board 1102 by example coupling components 1116. The coupling components 1116 may electrically and mechanically couple the package-on-interposer structure 1136 to the circuit board 1102, and may include solder balls (as shown in FIG. 11), male and female portions of a socket, an adhesive, an underfill material, and/or any other suitable electrical, chemical, and/or mechanical coupling structure.

The package-on-interposer structure 1136 may include an example IC package 1120 coupled to an example interposer 1104 by example coupling components 1118. The coupling components 1118 may take any suitable form for the application, such as the forms discussed above with reference to the coupling components 1116. Although a single IC package 1120 is shown in FIG. 11, multiple IC packages may be coupled to the interposer 1104. Additionally or alternatively, in some examples, additional interposers may be coupled to the interposer 1104. The interposer 1104 may provide an intervening substrate used to bridge the circuit board 1102 and the IC package 1120. The IC package 1120 may be or include, for example, a die (the die 902 of FIG. 9), an IC device (e.g., the IC device 1000 of FIG. 10), and/or any other suitable component(s). Generally, the interposer 1104 may spread a connection to a wider pitch or reroute a connection to a different connection. For example, the interposer 1104 may couple the IC package 1120 (e.g., a die) to a set of BGA conductive contacts of the coupling components 1116 for coupling to the circuit board 1102. In the example illustrated in FIG. 11, the IC package 1120 and the circuit board 1102 are attached to opposing sides of the interposer 1104. In other examples, the IC package 1120 and the circuit board 1102 may be attached to a same side of the interposer 1104. In some examples, three or more components may be interconnected by way of the interposer 1104.

In some examples, the interposer 1104 may be formed as a PCB, including multiple metal layers separated from one another by layers of dielectric material and interconnected by electrically conductive vias. In some examples, the interposer 1104 may be formed of an epoxy resin, a fiberglass-reinforced epoxy resin, an epoxy resin with inorganic fillers, a ceramic material, or a polymer material such as polyimide. In some examples, the interposer 1104 may be formed of alternate rigid or flexible materials that may include the same materials described above for use in a semiconductor substrate, such as silicon, germanium, and other group III-V and group IV materials. The interposer 1104 may include example metal interconnects 1108 and example vias 1110, including but not limited to example through-silicon vias (TSVs) 1106. The interposer 1104 may further include example embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The IC device assembly 1100 may include an example IC package 1124 coupled to the first face 1140 of the circuit board 1102 by example coupling components 1122. The coupling components 1122 may take the form of any of the examples discussed above with reference to the coupling components 1116, and the IC package 1124 may take the form of any of the examples discussed above with reference to the IC package 1120.

The IC device assembly 1100 illustrated in FIG. 11 includes an example package-on-package structure 1134 coupled to the second face 1142 of the circuit board 1102 by coupling components 1128. The package-on-package structure 1134 may include a first example IC package 1126 and a second example IC package 1132 coupled together by example coupling components 1130 such that the first IC package 1126 is disposed between the circuit board 1102 and the second IC package 1132. The coupling components 1128, 1130 may take the form of any of the examples of the coupling components 1116 discussed above, and the IC packages 1126, 1132 may take the form of any of the examples of the IC package 1120 discussed above.

FIG. 12 is a block diagram of an example electrical device 1200 that may include one or more of the example IC package 100. For example, any suitable ones of the components of the electrical device 1200 may include one or more of the device assemblies 1100, IC devices 1000, or dies 902 disclosed herein, and may be arranged in the example IC package 100. A number of components are illustrated in FIG. 12 as included in the electrical device 1200, but any one or more of these components may be omitted or duplicated, as suitable for the application. In some examples, some or all of the components included in the electrical device 1200 may be attached to one or more motherboards. In some examples, some or all of these components are fabricated onto a single system-on-a-chip (SoC) die.

Additionally, in some examples, the electrical device 1200 may not include one or more of the components illustrated in FIG. 12, but the electrical device 1200 may include interface circuitry for coupling to the one or more components. For example, the electrical device 1200 may not include an example display 1206, but may include display interface circuitry (e.g., a connector and driver circuitry) to which the display 1206 may be coupled. In some examples, the electrical device 1200 may not include an example audio input device 1218 (e.g., microphone) or an example audio output device 1208 (e.g., a speaker, a headset, earbuds, etc.), but may include audio input or output device interface circuitry (e.g., connectors and supporting circuitry) to which the audio input device 1218 or the audio output device 1208 may be coupled.

The electrical device 1200 may include example programmable or processor circuitry 1202 (e.g., one or more processing devices). The processor circuitry 1202 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The electrical device 1200 may include an example memory 1204, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1204 may include memory that shares a die with the processor circuitry 1202. This memory may be used as cache memory and may include embedded dynamic random access memory (eDRAM) or spin transfer torque magnetic random access memory (STT-MRAM).

In some examples, the electrical device 1200 may include an example communication chip 1212 (e.g., one or more communication chips). For example, the communication chip 1212 may be configured for managing wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1212 may operate in accordance with other wireless protocols in other examples. The electrical device 1200 may include an example antenna 1222 to facilitate wireless communications and/or to receive other wireless communications (such as AM or FM radio transmissions).

In some examples, the communication chip 1212 may manage wired communications, such as electrical, optical, or any other suitable communication protocols (e.g., the Ethernet). As noted above, the communication chip 1212 may include multiple communication chips. For instance, a first communication chip 1212 may be dedicated to shorter-range wireless communications such as Wi-Fi or Bluetooth, and a second communication chip 1212 may be dedicated to longer-range wireless communications such as global positioning system (GPS), EDGE, GPRS, CDMA, WiMAX, LTE, EV-DO, or others. In some examples, a first communication chip 1212 may be dedicated to wireless communications, and a second communication chip 1212 may be dedicated to wired communications.

The electrical device 1200 may include example battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include the display 1206 (or corresponding interface circuitry, as discussed above). The display 1206 may include any visual indicators, such as a heads-up display, a computer monitor, a projector, a touchscreen display, a liquid crystal display (LCD), a light-emitting diode display, or a flat panel display.

The electrical device 1200 may include the audio output device 1208 (or corresponding interface circuitry, as discussed above). The audio output device 1208 may include any device that generates an audible indicator, such as speakers, headsets, or earbuds.

The electrical device 1200 may include the audio input device 1218 (or corresponding interface circuitry, as discussed above). The audio input device 1218 may include any device that generates a signal representative of a sound, such as microphones, microphone arrays, or digital instruments (e.g., instruments having a musical instrument digital interface (MIDI) output).

The electrical device 1200 may include example GPS circuitry 1216. The GPS circuitry 1216 may be in communication with a satellite-based system and may receive a location of the electrical device 1200, as known in the art.

The electrical device 1200 may include any other example output device 1210 (or corresponding interface circuitry, as discussed above). Examples of the other output device 1210 may include an audio codec, a video codec, a printer, a wired or wireless transmitter for providing information to other devices, and/or an additional storage device.

The electrical device 1200 may include any other example input device 1220 (or corresponding interface circuitry, as discussed above). Examples of the other input device 1220 may include an accelerometer, a gyroscope, a compass, an image capture device, a keyboard, a cursor control device such as a mouse, a stylus, a touchpad, a bar code reader, a Quick Response (QR) code reader, any sensor, and/or a radio frequency identification (RFID) reader.

The electrical device 1200 may have any desired form factor, such as, for example, a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device (e.g., a smartwatch, a ring, googles, a headset, glasses, etc.). In some examples, the electrical device 1200 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

Example 1 includes a package substrate comprising a glass core having a cavity in an outer surface of the glass core, the outer surface defining a first plane, and a semiconductor die attached to a surface of the cavity, the semiconductor die having contact pads on a surface of the semiconductor die, the contact pads arranged in a second plane, the second plane substantially coplanar with the first plane.

Example 2 includes the package substrate of example 1, further including an adhesive material positioned in the cavity, the adhesive material contacting the surface of the cavity and the semiconductor die.

Example 3 includes the package substrate of example 1, wherein the surface of the cavity is a first surface, a second surface of the cavity positioned at a first angle relative to the outer surface of the glass core, and a third surface of the cavity positioned at a second angle relative to the outer surface, the second angle different than the first angle, the first surface distinct from the second surface and distinct from the third surface, the second surface distinct from the third surface.

Example 4 includes the package substrate of example 3, wherein the second angle associated with the second surface of the cavity is an acute angle.

Example 5 includes the package substrate of example 3, wherein the third surface of the cavity extends between the first surface of the cavity and the outer surface of the glass core.

Example 6 includes the package substrate of example 3, wherein the first surface of the cavity is recessed relative to the outer surface of the glass core, and the second surface of the cavity is recessed relative to the first surface of the cavity.

Example 7 includes the package substrate of example 6, further including a fourth surface of the cavity positioned between the second surface of the cavity and the outer surface of the glass core, the fourth surface of the cavity positioned at a third angle relative to the outer surface of the glass core.

Example 8 includes the package substrate of example 7, wherein the third angle associated with the fourth surface of the cavity positions the fourth surface of the cavity substantially parallel to the outer surface of the glass core.

Example 9 includes the package substrate of example 1, wherein the outer surface of the glass core is a first outer surface, the first outer surface opposing a second outer surface of the glass core, further including a via extending through the glass core from the cavity to the second outer surface.

Example 10 includes the package substrate of example 9, further including adhesive material in the via, the adhesive material extending at least partially into the cavity to contact the semiconductor die.

Example 11 includes the package substrate of example 10, wherein the adhesive material covers an inner wall of the via from the semiconductor die to the second outer surface.

Example 12 includes an integrated circuit (IC) package comprising a package substrate having a glass core including a cavity positioned in an outer surface of the glass core, and a semiconductor die supported by a recessed surface of the glass core in the cavity, the semiconductor die having a first side and a second side opposite the first side, the first side to face the recessed surface, the second side substantially flush with the outer surface of the glass core.

Example 13 includes the IC package of example 12, further including an adhesive material in the cavity to bond the semiconductor die to the glass core.

Example 14 includes the IC package of example 12, further including a via extending through the glass core, the semiconductor die positioned between the via and the outer surface of the glass core.

Example 15 includes the IC package of example 14, further including an adhesive material to fill the via, the adhesive material extending at least partially into the cavity to bond the semiconductor die to the glass core.

Example 16 includes the IC package of example 12, further including a ridge positioned in the cavity, the ridge extending from a sidewall of the cavity towards the semiconductor die and extending from the recessed surface towards the outer surface of the glass core.

Example 17 includes the IC package of example 16, wherein the ridge includes a first surface, a second surface, and a third surface, the third surface positioned between the first surface and the second surface, the first surface positioned at a first angle relative to the outer surface of the glass core, the second surface positioned at a second angle relative to the recessed surface, the third surface positioned at a third angle relative to the recessed surface.

Example 18 includes a method comprising providing a glass core, the glass core including a cavity in a surface of the glass core, and depositing a capacitor in the cavity, the cavity dimensioned to position a surface of the capacitor substantially flush with the surface of the glass core.

Example 19 includes the method of example 18, further including providing a slanted surface in the cavity, the slanted surface slanted relative to a sidewall of the cavity and slanted relative to a support surface of the cavity, the capacitor mounted to the support surface.

Example 20 includes the method of example 18, wherein the cavity includes a first cavity and a second cavity positioned in a surface of the first cavity, the capacitor mounted to a surface of the second cavity.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A package substrate comprising:
a glass core having a cavity in an outer surface of the glass core, the outer surface defining a first plane; and
a semiconductor die attached to a surface of the cavity, the semiconductor die having contact pads on a surface of the semiconductor die, the contact pads arranged in a second plane, the second plane substantially coplanar with the first plane.

2. The package substrate of claim 1, further including an adhesive material positioned in the cavity, the adhesive material contacting the surface of the cavity and the semiconductor die.

3. The package substrate of claim 1, wherein the surface of the cavity is a first surface, a second surface of the cavity positioned at a first angle relative to the outer surface of the glass core, and a third surface of the cavity positioned at a second angle relative to the outer surface, the second angle different than the first angle, the first surface distinct from the second surface and distinct from the third surface, the second surface distinct from the third surface.

4. The package substrate of claim 3, wherein the second angle associated with the second surface of the cavity is an acute angle.

5. The package substrate of claim 3, wherein the third surface of the cavity extends between the first surface of the cavity and the outer surface of the glass core.

6. The package substrate of claim 3, wherein the first surface of the cavity is recessed relative to the outer surface of the glass core, and the second surface of the cavity is recessed relative to the first surface of the cavity.

7. The package substrate of claim 6, further including a fourth surface of the cavity positioned between the second surface of the cavity and the outer surface of the glass core, the fourth surface of the cavity positioned at a third angle relative to the outer surface of the glass core.

8. The package substrate of claim 7, wherein the third angle associated with the fourth surface of the cavity positions the fourth surface of the cavity substantially parallel to the outer surface of the glass core.

9. The package substrate of claim 1, wherein the outer surface of the glass core is a first outer surface, the first outer surface opposing a second outer surface of the glass core, further including a via extending through the glass core from the cavity to the second outer surface.

10. The package substrate of claim 9, further including adhesive material in the via, the adhesive material extending at least partially into the cavity to contact the semiconductor die.

11. The package substrate of claim 10, wherein the adhesive material covers an inner wall of the via from the semiconductor die to the second outer surface.

12. An integrated circuit (IC) package comprising:
a package substrate having a glass core including a cavity positioned in an outer surface of the glass core; and
a semiconductor die supported by a recessed surface of the glass core in the cavity, the semiconductor die having a first side and a second side opposite the first side, the first side to face the recessed surface, the second side substantially flush with the outer surface of the glass core.

13. The IC package of claim 12, further including an adhesive material in the cavity to bond the semiconductor die to the glass core.

14. The IC package of claim 12, further including a via extending through the glass core, the semiconductor die positioned between the via and the outer surface of the glass core.

15. The IC package of claim 14, further including an adhesive material to fill the via, the adhesive material extending at least partially into the cavity to bond the semiconductor die to the glass core.

16. The IC package of claim 12, further including a ridge positioned in the cavity, the ridge extending from a sidewall of the cavity towards the semiconductor die and extending from the recessed surface towards the outer surface of the glass core.

17. The IC package of claim 16, wherein the ridge includes a first surface, a second surface, and a third surface, the third surface positioned between the first surface and the second surface, the first surface positioned at a first angle relative to the outer surface of the glass core, the second surface positioned at a second angle relative to the recessed surface, the third surface positioned at a third angle relative to the recessed surface.

18. A method comprising:
providing a glass core, the glass core including a cavity in a surface of the glass core; and
depositing a capacitor in the cavity, the cavity dimensioned to position a surface of the capacitor substantially flush with the surface of the glass core.

19. The method of claim 18, further including providing a slanted surface in the cavity, the slanted surface slanted relative to a sidewall of the cavity and slanted relative to a support surface of the cavity, the capacitor mounted to the support surface.

20. The method of claim 18, wherein the cavity includes a first cavity and a second cavity positioned in a surface of the first cavity, the capacitor mounted to a surface of the second cavity.
